(19) United States
(12) Patent Application Publication
(10) Pub. No.: US 2010/0102833 A1
(43) Pub. Date: Apr. 29, 2010

(54) SITTING DETECTION SYSTEM

(75) Inventors: Hideki UNO, Kariya-shi (JP); Fumitoshi AKAIKE, Kariya-shi (JP); Haruki UNOU, Kariya-shi (JP)

Correspondence Address: GREENBLUM & BERNSTEIN, P.L.C., 1950 ROLAND CLARKE PLACE, RESTON, VA, 20191, US

(73) Assignee: TOYOTA BOSHOKU KABUSHIKI KAISHA, Aichi-ken (JP)

(21) Appl. No.: 12/575,565

(22) Filed: Oct. 8, 2009

(30) Foreign Application Priority Data
Oct. 27, 2008 (JP) 2008-2760914

(51) Int. Cl. G01R 27/26

(52) U.S. Cl. 324/679

(57) ABSTRACT

A sitting detection system determines whether an occupant is seated in a vehicle seat or not by applying a DC voltage to a sheet-like detection electrode that is provided in the seat, and measuring the time for capacitance between the detection electrode and a ground to be charged to a predetermined level using simple implement. The use of the conductive woven cloth, which is formed with the surface member of the seat, as the detection electrode enables not to degrade the texture of the seat. The threshold time for detecting whether an occupant is seated in a seat or not may be set using a charging time which is measured when no occupant is seated in the seat as the initial value.

### CROSS-REFERENCE TO RELATED APPLICATIONS

The present application claims priority under 35 U.S.C. §119 of Japanese Patent Application No. 2008-276091, filed on Oct. 27, 2008, the disclosure of which is expressly incorporated by reference herein in its entirety.

### BACKGROUND OF THE INVENTION

1. Field of the Invention

The present invention generally relates to a sitting detection system that determines if an occupant is seated in a vehicle seat or not, by detecting a change in capacitance between an electrode and a ground which are provided in the vehicle seat.

2. Description of the Related Art

In automobiles, detection information of whether an occupant is seated in a seat or not is used for seatbelt warning, determination of airbag deployment and so on. A vehicle airbag device is controlled to deploy an airbag in a vehicle accident if the occupant is seated in a seat, and not to deploy the airbag if no occupant is seated in the seat. For such purposes, various methods have been used to detect a sitting state of the occupant. Representative examples of such methods include a sensor that detects the weight of the occupant, and a sensor that detects capacitance.

First, in the sitting detection by detecting the weight of the occupant, a plurality of weight sensors (sheet-like switches), which are rendered conductive by the weight of the occupant, are provided in the upper surface of a seat cushion. When rendered conductive, the weight sensors detect that the occupant is seated in the seat. In a known weight sensor, two films, having electrical contact points formed on the opposing surfaces of the two films, are provided spaced apart in a vertical direction. When the weight of the occupant is applied to the films, the films are deformed, and the contact points are brought into contact with each other, whereby the films are rendered conductive. Thus, the weight sensor detects that the occupant is seated in the seat (see, e.g., Related Art 1).

However, the sensor having such a mechanical structure has poor water resistance and poor durability, causing a problem that the sensor tends to have defective conduction. For example, water can enter the sensor from the end of the mating surfaces of the films which form a switch, causing a defective switch function. Even if the end faces of the mating surfaces of the films are fixed together, welded together, or the like, the films are repeatedly subjected to compression and deformation when the occupant is seated in the seat. This can cause cracks and fatigue fractures, thereby reducing the water resistance.

Moreover, in some cases, the weight-detection type sitting sensor has problems that the sensor cannot detect the occupant when the weight of the occupant is light, such as a child, and that, when a heavy object is placed on the seat, the sensor wrongly detects the object as the occupant.

In addition, a capacitive sitting detection system is known in the art. Since a human body is a dielectric body, capacitance, which is generated between a detection electrode provided in a seat surface and a backrest portion of a seat and a ground of a vehicle, varies between when the occupant is seated in the seat and when no occupant is seated in the seat. The sitting detection system detects this change in capacitance from a change in voltage and current, disturbance of an electric field, and the like, thereby detecting that the occupant is seated in the seat. Many capacitive sitting detection systems apply an alternating current (AC) (high frequency) signal to the detection electrode, and determine a sitting state of the occupant based on a received signal (see, e.g., Related Art 2).

However, since such sitting sensor supplies a high frequency signal of several tens of kilohertz to several hundreds of kilohertz to the electrode provided in the seat, high frequency noise may be radiated and may affect peripheral electronic devices. There is also a problem that the sitting sensor is susceptible to ambient noise and the like.

[Related Art 1] Japanese Patent Application Laid-Open No. 2005-153556

[Related Art 2] Japanese Patent Application Laid-Open No. 2006-201129

### SUMMARY OF THE INVENTION

As described above, the conventional sitting detection system that detects whether the occupant is seated in a vehicle seat or not has problems that the sensor having electrical contacts has poor water resistance and poor durability, and that it is impossible to distinguish the occupant from luggage by detecting only the weight. The capacitive sensor using a high frequency signal has a problem of EMC (electromagnetic compatibility) such as high frequency noise being radiated from the electrode.

Moreover, in the case of the weight sensor, a film-like sensor is embedded in the seat, and in the case of the capacitive sensor, an electrode is provided near the surface of the seat. This has a problem of reducing air permeability in the state where the occupant is seated in the seat, thereby degrading the texture of the seat.

The present invention has been developed in view of the above problems, and it is an object of the present invention to provide a sitting detection system capable of accurately and stably detecting whether the occupant is seated in a seat or not, having high durability and high reliability, and providing excellent texture of the seat.

In a non-limiting embodiment of the present invention, a sitting detection system is provided. The sitting detection system is for detecting whether an occupant is seated in a seat or not based on a change in capacitance between a seat of a vehicle and a ground. The sitting detection system may include a sheet-like detection electrode, a voltage application circuit, a voltage detection circuit and a processing unit. The sheet-like detection electrode is provided in a seat surface portion of the seat, or in the seat surface portion and a backrest portion of the seat, for detecting the occupant. The voltage application circuit applies a DC voltage to charge the capacitance between the ground and the detection electrode. The voltage detection circuit detects that a voltage between the ground and the detection electrode has reached a predetermined threshold voltage. The processing unit measures a charging time from the application of the DC voltage by the voltage application circuit to the detection by the voltage detection circuit, and compares the charging time with a predetermined threshold time to determine if the occupant is seated on the seat or not.

In other non-limiting embodiments, the detection electrode may be made of a conductive woven cloth, and the conductive woven cloth may be formed as a surface member of the seat, or is provided immediately under the surface member.

In further non-limiting embodiments, the conductive woven cloth may be a woven cloth having conductive fibers woven therein at regular intervals.

In still other non-limiting embodiments, the processing unit may include an oscillation circuit, and the processing unit may measure the charging time by counting the number of pulse signals of a fixed period which are generated by the oscillation circuit, during a period from the application of the DC voltage by the voltage application circuit to the detection by the voltage detection circuit.

In still further non-limiting embodiments, the processing unit may measure the charging time by applying the DC voltage in every predetermined period.

In yet even further non-limiting embodiments, the processing unit may measure the charging time in a state where the occupant is not seated in the seat, and sets the predetermined threshold time based on the measured charging time.

The sitting detection system according to the present invention determines whether the occupant is seated in the seat or not by applying the DC voltage to the sheet-like detection electrode provided in the seat surface portion and the like of the vehicle seat, by measuring the charging time for the voltage of the detection electrode to reach the predetermined threshold voltage as a result of charging of the capacitance between the ground and the detection electrode of the vehicle, and comparing the charging time with the predetermined threshold time. Since this sitting detection system has neither a mechanical structure nor contact points, the sitting detection system has high water resistance and high durability, and is capable of easily distinguishing a human being having a high dielectric constant from an object placed on the seat. Moreover, since no AC (high frequency) signal is applied to the detection electrode, no high frequency noise, which affects peripheral electronic devices, is radiated from the electrode. Moreover, since the sitting detection system measures the charging time, the sitting detection system is less susceptible to noise and has high stability, and a highly reliable sitting detection system can be provided by a small number of parts.

Moreover, in the case where the detection electrode is made of a conductive woven cloth, and the conductive woven cloth is formed as the surface member of the seat, or is provided immediately under the surface member, the shape and dimensions of the detection electrode can be designed with a larger degree of freedom, and the detection electrode can be integrally formed as a part of the exterior of the seat. In addition, the detection electrode does not degrade the texture and the air permeability of the seat.

In the case where the conductive woven cloth is a woven cloth having conductive fibers woven therein at regular intervals, a highly durable, economical detection electrode can be implemented without degrading the texture and the air permeability of the seat.

Measuring the charging time by counting the number of pulse signals generated by the oscillation circuit enables stable measurement with a simple circuit, thereby facilitating the comparison process with the threshold time which is performed to determine if the occupant is seated in the seat or not.

Measuring the charging time by applying the DC voltage to the detection electrode in every predetermined period enables the change in capacitance to be reliably detected, and also enables the determination of whether the occupant is seated in the seat or not to be made with improved stability.

Measuring the charging time in the state where the occupant is not seated in the seat, and setting the threshold time based on the measured charging time enables an appropriate threshold time to be set regardless of the vehicle type even when environmental conditions change. This eliminates the need for vehicle-by-vehicle adjustment, thereby enabling accurate determination of whether the occupant is seated in the seat or not.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 is a schematic diagram illustrating a schematic structure of a sitting detection system of the present invention;

FIG. 2 is a block diagram of the sitting detection system of the present invention.

FIG. 3 is an equivalent circuit diagram mainly showing a sensor unit in the state where no occupant is seated in a seat;

FIG. 4 is an equivalent circuit diagram mainly showing the sensor unit in the state where an occupant is seated in a seat;

FIG. 5 is a graph illustrating how a voltage between a detection electrode and a ground changes with time;

FIG. 6 is a circuit diagram showing a structural example of a voltage application circuit and a voltage detection circuit;

FIG. 7 is a block diagram showing a structural example of a unit that measures a charging time;

FIG. 8 is a timing chart illustrating operation of the sitting detection system of the present invention; and

FIG. 9 is a flowchart illustrating an example of a method for controlling the sitting detection system of the present invention.

### DESCRIPTION OF THE PREFERRED EMBODIMENTS

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

A sitting detection system of the present invention includes a sheet-like conductor provided in a seat surface portion of a vehicle seat, or in the seat surface portion and a backrest portion of the vehicle seat, and detects if an occupant is seated in the seat or not by detecting a change in capacitance between a seat frame (a ground) and the conductor according to the charging time of the capacitance.

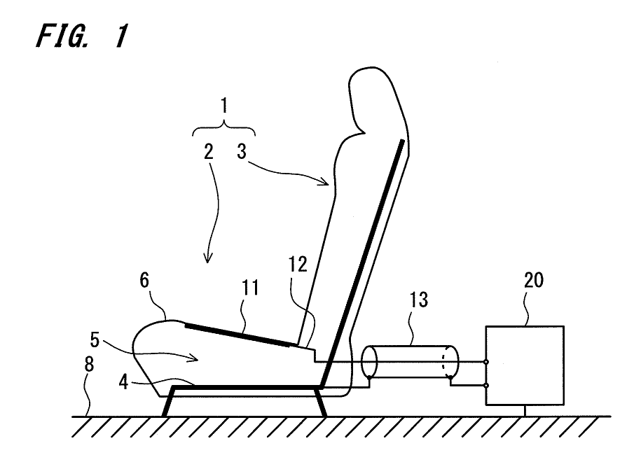

FIG. 1 is a schematic diagram showing a schematic structure of the sitting detection system of the present invention.

In FIG. 1, reference numeral 1 indicates a seat such as a passenger's seat (a driver's seat) or a back seat of a vehicle. The seat 1 includes a seating portion 2 and a backrest portion 3. The seat 1 has a metal seat frame 4 inside, and is fixed on a floor portion 8 of a vehicle body by the seat frame 4. Note that illustration of a slide mechanism, a pivot mechanism of the backrest portion, other details, and the like, which are commonly provided in the vehicle seat, is omitted in FIG. 1.

In the seating portion 2 of the seat, a cushion member 5, which is made of a material such as urethane foam, is provided on the seat frame 4. The surface of the seating portion 2 is covered by a surface member 6 such as a woven cloth. The backrest portion 3 is similarly formed by the seat frame 4, a cushion member, a surface material, and the like.

A conductive sheet-like detection electrode 11 that detects if the occupant is seated in the seat is provided in a seat surface portion of the seating portion 2 of the seat. The detection electrode 11 may be provided in the backrest portion 3 in addition to the seat surface portion, and the respective electrodes provided in the seat surface portion and the backrest portion may be connected to each other by a conductor (not shown). The detection electrode 11 may form a part of the surface member that covers the seat 1, or may be inserted immediately under the surface member (between the surface member and the cushion member). Various kinds of materials may be used as the detection electrode 11 as long as the materials are conductors. For example, a conductive cloth, a conductive film, a metal plate, a metal wire mesh, or the like may be used as the conductive electrode 11.

The shape and dimensions of the detection electrode 11 are not specifically limited. The shape and dimensions of the detection electrode 11 may be determined according to the size and shape of the seating portion or the backrest portion of the seat. Alternatively, the electrode may be provided only in a portion that is in contact with the body of the occupant when the occupant is seated in the seat. The detection electrode 11 need not necessarily be formed by one sheet, but a plurality of electrode sheets may be arranged and electrically connected to each other.

Preferably, a conductive woven cloth may be used as the detection electrode 11. The “conductive woven cloth” herein refers to a cloth having conductive fibers woven therein as appropriate. Examples of the conductive fibers include stainless steel wires, carbon fibers, and plated fibers. The use of the conductive woven cloth as the detection electrode 11 enables the shape, dimensions, and the like of the detection electrode 11 to be designed as desired, and also enables the detection electrode 11 to be formed integrally with the surface member that forms other portion of the seat. Moreover, the electrode made of the conductive woven cloth does not reduce air permeability, and does not degrade the texture of the seat.

A durable, economical detection electrode can be implemented by using, for example, a woven cloth having conductive fibers, such as stainless steel wires, woven therein at intervals of about 2 to 3 mm, as the conductive woven cloth.

A lead wire 12 is extended from the detection electrode 11. The lead wire 12 is connected to an electronic control unit (ECU) 20 through a shielded cable 13.

The seat frame 4 may be used as an electrode on the ground side. Since the seat frame 4 is fixed to the floor portion 8 of the vehicle body, the seat frame 4 has a ground potential of the vehicle. In the following description, the ground potential of the vehicle is referred to as the “ground,” and the seat frame is also referred to as the “ground electrode.” The ground electrode is connected to the ECU 20 by an electric wire. The electric wire can be connected through a shielding conductor of the shielded cable 13.

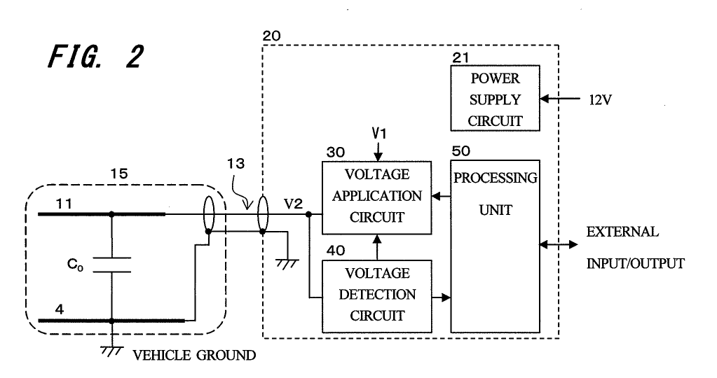

FIG. 2 is a block diagram showing a structure of the sitting detection system.

A sensor unit 15 includes the detection electrode 11 formed in the seat surface portion of the seat, or in the seat surface portion and the backrest portion of the seat, and the ground electrode 4. The sensor unit 15 is connected to the ECU 20 through the shielded cable 13. In FIG. 2, reference character C₀ indicates the sum of capacitance generated by the cushion material and other peripheral portions of the seat, which are provided between the detection electrode 11 and the ground electrode 4, and indicates capacitance that is generated between the detection electrode 11 and the ground electrode 4 regardless of whether the occupant is seated in the seat or not.

The ECU 20 includes a power supply circuit 21, a voltage application circuit 30, a voltage detection circuit 40, and a processing unit 50. As shown in FIG. 2, reference character V₁ indicates a direct current (DC) voltage that is applied to the detection electrode 11, and reference character V₂ indicates a potential of the detection electrode 11, that is, a voltage between the detection electrode 11 and the ground electrode 4.

The power supply circuit 21 receives a power supply of 12 V from a vehicle battery, and generates a DC voltage V₁ which is to be applied to the detection electrode 11, and a system power source which is to be supplied to electric circuits in the ECU 20. The DC voltage V₁ may be the same voltage as the system power supply (e.g., 5 V). If the power supply is shared, the voltage V₁ can be generated with a smaller number of parts at low cost.

The voltage application circuit 30 and the voltage detection circuit 40 in the ECU 20 are connected to the sensor unit 15 through the cable 13. The voltage application circuit 30 is a circuit that applies the DC voltage V₁ to the detection electrode 11. The voltage detection circuit 40 is a circuit that detects that the voltage V₂ between the detection electrode 11 and the ground electrode 4 has reached a predetermined threshold voltage. The voltage application circuit 30 and the voltage detection circuit 40 are connected to a processing unit 50.

The processing unit 50 controls application of the DC voltage by the voltage application circuit 30. The processing unit 50 measures the time (the charging time) from the start of application of the DC voltage to the detection by the voltage detection circuit 40, and compares the measured value with a predetermined threshold time to determine if the occupant is seated in the seat or not. Thus, the processing unit 50 includes a timer unit that measures the charging time. In addition, the processing unit 50 stores the threshold time data which is used to determine a sitting state of the occupant, and includes a program for executing control, setting the threshold value, making the determination, and the like. Moreover, the processing unit 50 may include an external input/output which, for example, outputs the determination result. The processing unit 50 may be formed by a microcontroller (an embedded microcomputer) and a peripheral circuit.

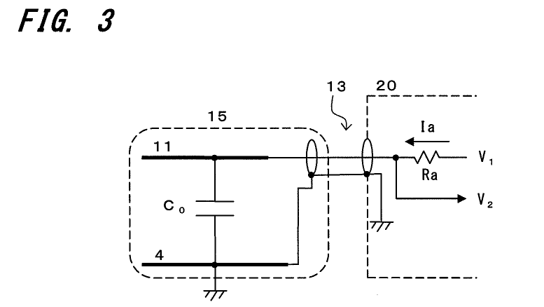

FIG. 3 is an equivalent circuit diagram showing mainly the sensor unit 15 in the state where no occupant is seated in the seat. In FIG. 3, reference character C₀ indicates capacitance that is generated between the detection electrode 11 and the ground electrode 4 by the cushion member of the seat and the like, as described above, and reference character Ra indicates a resistive element that limits a current.

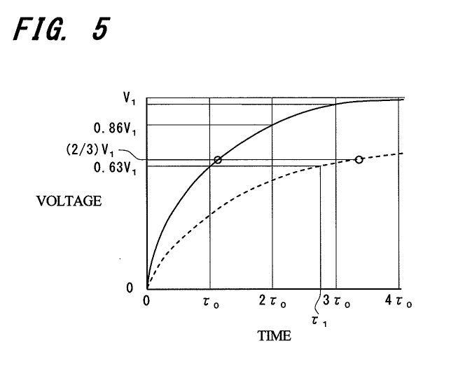

In an initial state, the detection electrode 11 has the same potential as that of the ground electrode 4. When the DC voltage V₁ is applied in this state to the detection electrode 11 through the resistor Ra included in the voltage application circuit 30, a current Ia flows, and charging of the capacitance C₀ is started. In this case, the voltage V₂ between the detection electrode 11 and the ground electrode 4 increases with time, as shown by solid line in FIG. 5. The voltage V₂ becomes 0.63V₁ at time τ₀, where τ₀ is a time constant, and in this circuit, τ₀=Ra·C₀.

Next, when the occupant is seated in the seat, the body of the occupant is interposed between the detection electrode 11 and the ground. A human body is a dielectric body, and has a larger relative dielectric constant than that of air. Thus, capacitance is generated by the human body interposed between the detection electrode 11 and the ground electrode 4, and the capacitance between these electrodes is significantly increased as compared to the case where no occupant is seated in the seat.

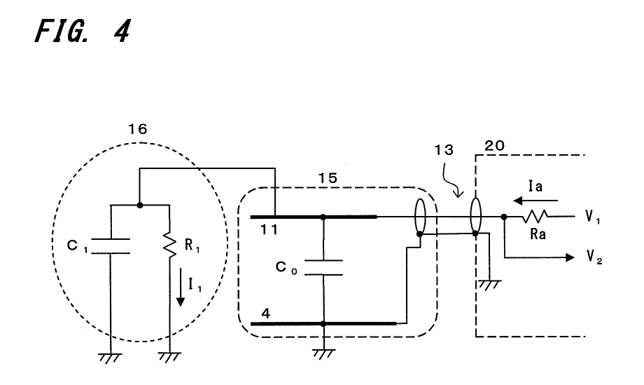

FIG. 4 is an equivalent circuit diagram showing mainly the sensor unit 15 in the state where the occupant is seated in the seat. In FIG. 4, reference character C₁ indicates capacitance that is generated between the detection electrode 11 and the ground by a body 16 of the occupant. This sitting detection system detects a change in the sum of the capacitance values C₀ and C₁ between the detection electrode 11 and the ground. In the state where the occupant is seated in the seat, the capacitance becomes (C₀+C₁). When the DC voltage V₁ is applied in this state to the detection electrode 11 through the resistor Ra, charging of the capacitance (C₀+C₁) is started by the current Ia, and the voltage V₂ between the detection electrode 11 and the ground electrode 4 increases as shown by the broken line in FIG. 5. Provided that τ₁ is a time constant in this case, τ₁=Ra·(C₀+C₁).

This sitting detection system detects the change in the capacitance by measuring the time (the charging time) for the voltage V₂ of the detection electrode 11 to reach a predetermined threshold voltage. If the predetermined threshold voltage is 0.63V₁, the charging time is τ₀ when no occupant is seated in the seat, and is τ₁ when the occupant is seated in the seat.

The actual sum of the capacitance values C₀ and C₁ varies depending on the vehicle type. In an actual measurement example of small cars, the capacitance (C₀) in the state where no occupant is seated in the seat is about 50 pF, while the capacitance (C₀+C₁) in the state where the occupant (an adult) is seated in the seat is about 150 pF. In this case, if the resistor Ra has a resistance value of 500 kΩ, τ₀=about 25 μs, and τ₁=about 75 μs. There is a large difference in charging time between when no occupant is seated in the seat and when the occupant is seated in the seat, and this difference is large enough for the system to detect if the occupant is seated in the seat or not.

It is now assumed that a child seat, luggage, or the like is placed on the seat. These objects have a smaller relative dielectric constant than that of a human body, and thus generate small capacitance C₁. It is therefore easy to distinguish such an object placed on the seat from a human being (an adult) seated in the seat.

More specifically, when the occupant is seated in the seat, C₀ may increase as compared to the case where no occupant is seated in the seat, thereby causing a leakage current to flow between the detection electrode 11 and the vehicle body (the ground) via the human body. That is, when the occupant is seated in the seat, the cushion member in the seat is compressed, whereby the distance between the electrodes is reduced. Moreover, in the case where the detection electrode 11 is made of a conductive woven cloth, the conductive woven cloth is extended and deformed so as to increase the area. Thus, C₀ may increase as compared to the case where no occupant is seated in the seat. Moreover, in the case where the body of the occupant is in contact with the floor surface of the vehicle or the like, a leakage current I₁ shown in FIG. 4 flows.

However, even if C₀ increases and the leakage current I₁ is generated in the state where the occupant is seated in the seat, this causes the potential of the detection electrode 11 to increase more gradually, thereby increasing the time for the voltage V₂ to reach the predetermined threshold voltage. That is, this acts in such a direction that facilitates detection of whether the occupant is seated in the seat or not. Thus, description of the change in C₀ and influences of the leakage current I₁ will be omitted.

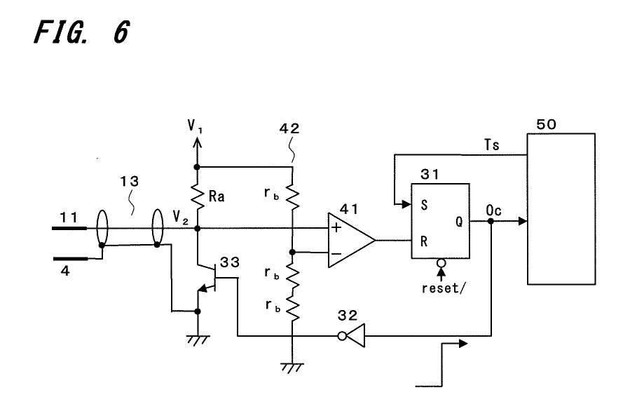

FIG. 6 is a specific structural example of the voltage application circuit 30 and the voltage detection circuit 40.

The voltage application circuit 30 is formed by a flip-flop 31, a switch element (such as a transistor) 33, a resistor Ra, and the like. The processing unit 50 outputs a signal Ts to an S-terminal of the flip-flop 31. The signal Ts is a signal that indicates the start of voltage application.

The voltage detection circuit 40 includes a comparator 41 and a voltage divider circuit 42. An output signal of the comparator 41 is connected to an R-terminal of the flip-flop 31 of the voltage application circuit 30.

The voltage divider circuit 42 is a circuit that sets a threshold voltage. In this example, since the voltage divider circuit 42 is formed by three resistors r_{b} having the same resistance value, the threshold voltage is (⅔)V₁. The method of setting the threshold voltage is not limited to the structure of this example. The resistance values and the combination thereof may be modified as appropriate. Alternatively, a signal of an appropriate level may be applied as a threshold voltage to the comparator 41 by using an output of the microcontroller included in the processing unit 50.

Operation of the circuit shown in FIG. 6 will be described below. In an initial state, an output signal Oc of the flip-flop 31 is reset to an OFF state, and the switch element 33 is in an ON state. Thus, the detection electrode 11 has the same potential as that of the ground electrode 4. In response to the start signal Ts from the processing unit 50, the output signal Oc of the flip-flop 31 is set to the ON state, and the switch element 33 is turned OFF. Thus, the DC voltage V₁ is applied to the detection electrode 11 through the resistor Ra, and charging of the capacitance between the detection electrode 11 and the ground electrode 4 is started.

The voltage V₂ of the detection electrode 11 is input to the comparator 41, and is compared with the threshold voltage (⅔)V₁ which is set by the voltage divider circuit 42. When the voltage V₂ exceeds the threshold voltage (⅔)V₁, the output of the comparator 41 is set to the ON state, and the output signal Oc of the flip-flop 31 is reset to an OFF state, whereby the switch element 33 is turned ON. Thus, electric charge accumulated in the capacitance between the detection electrode 11 and the ground electrode 4 is discharged, whereby the operation state returns to the initial state.

The charging time from the start of charging of the capacitance between the detection electrode 11 and the ground electrode 4 until the voltage V₂ of the detection electrode 11 reaches the predetermined threshold voltage is the time during which the output signal Oc of the flip-flop 31 is held in a set state (the ON state) after the start signal Ts is applied from the processing unit 50.

The charging time may be measured by various methods. For example, a timer circuit that measures the charging time may be provided, or the signal Oc may be input to the microcontroller to measure the time by a software timer.

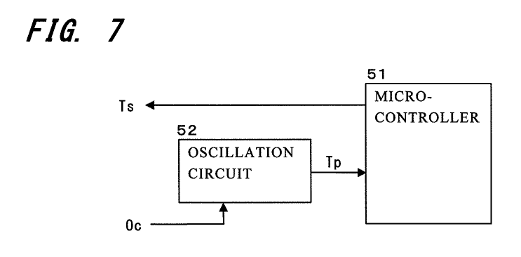

FIG. 7 shows a structural example of measuring the charging time by providing an oscillation circuit 52 in the processing unit 50. The oscillation circuit 52 is structured to output a pulse signal Tp having a fixed period while the signal Oc is ON. The charging time can be measured by counting the number of pulse signals Tp by a microcontroller 51. The period of the pulse signal Tp may be determined as appropriate according to the required resolution.

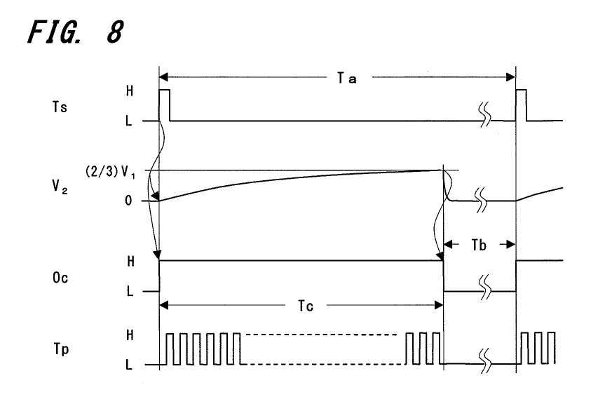

FIG. 8 is a timing chart showing a method for measuring the charging time of the capacitance between the detection electrode and the ground. As described above, reference character Ts indicates a start signal that is output from the processing unit 50, reference character V₂ indicates a voltage between the detection electrode 11 and the ground electrode 4, reference character Oc indicates an output signal of the voltage application circuit 30, and reference character Tp is a pulse signal of a fixed period which is generated by the oscillation circuit 52.

Before the start signal Ts is applied, the detection electrode has the same potential as that of the ground (V₂=0 V).

When the start signal Ts is output (H), the voltage application circuit applies the DC voltage V₁ to the detection electrode. As a result, charging of the capacitance is started, and the voltage V₂ of the detection electrode increases with time. At the same time, the output signal Oc of the voltage application circuit is set to the ON (H) state, and the oscillation circuit outputs the pulse signal Tp.

When the capacitance is charged, and the potential V₂ of the detection electrode reaches the predetermined threshold voltage (in this example, (⅔)V₁), the output signal Oc of the voltage application circuit is reset to an OFF (L) state, and output of the pulse signal Tp is stopped.

Provided that the charging time is “Tc,” the charging time Tc can be obtained by counting the number of pulse signals Tp by the processing unit.

The processing unit can detect a change in capacitance between the detection electrode and the ground by repeatedly measuring the charging time Tc in a periodic manner. FIG. 8 shows that the start signal Ts is output in every period Ta. The measurement period Ta can be determined as appropriate. For example, the measurement period Ta can be set to about several tens of milliseconds to about several hundreds of milliseconds.

The processing unit determines if the occupant is seated in the seat or not by comparing the measured charging time Tc with the predetermined threshold time. That is, provided that the predetermined threshold time is “Th,” the processing unit determines that the occupant is seated in the seat, if the measured charging time Tc is larger than the threshold time Th. Thus, the data of the threshold time Th is stored in the processing unit.

The capacitance between the detection electrode and the ground electrode in the seat varies significantly between when the seat is not occupied and when the occupant is seated in the seat, depending on the vehicle type. In actual measurement examples where the detection electrode is provided in the seat surface of the seat, the capacitance in the state where the seat is not occupied is about 50 pF in a small passenger car, and is about one hundred and several tens of picofarads in a large passenger car. When the occupant (an adult) is seated in the seat, the respective capacitance values in the small passenger car and the large passenger car become about three times the respective capacitance values obtained when the seat is not occupied in the small passenger car and the large passenger car. In this case, the charging time Tc when the occupant is seated in the seat is about three times the charging time Tc when the seat is not occupied.

Based on the above example, as the easiest method, the threshold time Th can be set by a fixed ratio based on T₀, where T₀ is the average charging time of each vehicle type when the seat is not occupied. For example, in the vehicle type in which the average charging time is 25 μs when the seat is not occupied, the threshold time Th can be set to 38 μs, which is 1.5 times the average charging time when the seat is not occupied. Thus, when the charging time Tc exceeds 38 μs, it can be determined that the occupant is seated in the seat. In the above example, the charging time Tc is about 75 μs when the occupant is seated in the seat. Thus, whether the occupant is seated in the seat or not can be determined based on the above threshold value.

It is to be understood that, regarding the method of setting the threshold time Th and the method of determining whether the occupant is seated in the seat or not, accuracy and stability of the detection can be improved by devising an algorithm.

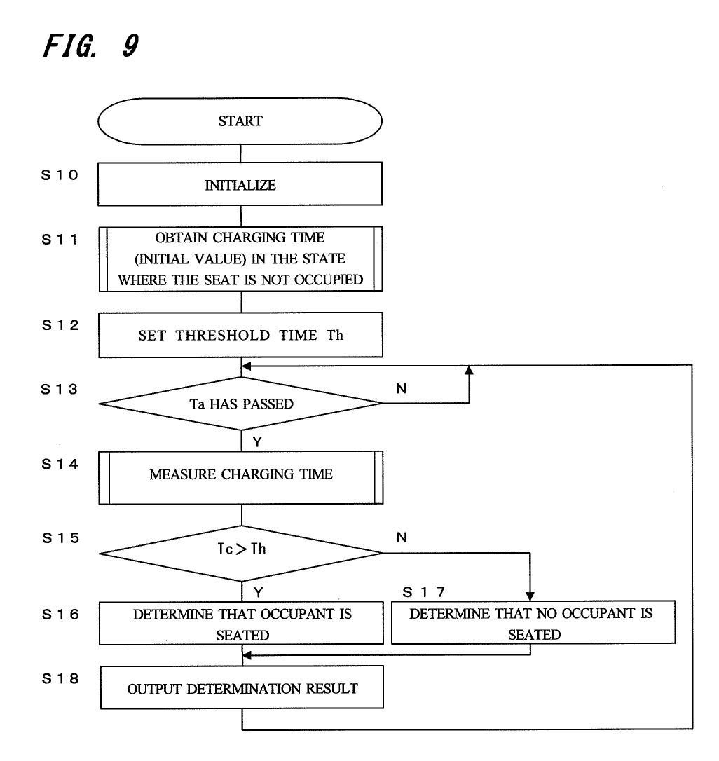

FIG. 9 shows an example in which the threshold time is set by obtaining the charging time when no occupant is seated in the seat. In this example, the method of measuring the charging time (Tc) is as described above.

After the system is initialized (S10), the charging time when the seat is not occupied is obtained as an initial value (S11). The initial value may be a predetermined time based on the vehicle type.

Preferably, whether the occupant is seated in the seat or not can be detected more accurately by using the charging time Tc, which is measured when no occupant is seated in the seat, as an initial value. For example, the charging time Tc in the state where the seat is not occupied, which is measured after the system is started, may be used as an initial value, or the charging time Tc in the state where the seat is not occupied, which was measured by the system in the past and is stored in the system, may be used as an initial value. Moreover, a default threshold time may be corrected based on the measured charging time Tc obtained when the seat is not occupied.

The use of the charging time, which is measured when no occupant is seated in the seat, as the initial value eliminates the need to, for example, adjust the charging time on a vehicle-by-vehicle basis, and also enables accurate detection according to a change in environmental conditions.

Next, the threshold time Th is set based on the obtained initial value (S12). An algorithm for setting the threshold time Th can be determined as appropriate so that whether the occupant is seated in the seat or not can be determined stably even in case of variation or the like due to the environmental conditions.

This system is capable of measuring the charging time Tc at predetermined time intervals Ta (S13, S14). The system compares the measured value Tc with the threshold time Th (S15). If the measured value Tc exceeds the threshold time Th, the system determines that the occupant is seated in the seat. If not, the system determines that no occupant is seated in the seat (S15 to S17).

An electric signal can be output to an external airbag control device, an external seatbelt warning device, and the like according to the determination result (S18). Thus, deployment of an airbag can be inhibited when the seat is not occupied, and can be allowed when the occupant (an adult) is seated in the seat.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A sitting detection system that detects whether an occupant is seated in a seat or not based on a change in capacitance between a seat of a vehicle and a ground, comprising:
a sheet-like detection electrode that is provided in a seat surface portion of said seat, or in said seat surface portion and a backrest portion of said seat, for detecting the occupant;
a voltage application circuit that applies a DC voltage to charge the capacitance between said ground and said detection electrode;
a voltage detection circuit that detects that a voltage between said ground and said detection electrode has reached a predetermined threshold voltage, and
a processing unit that measures a charging time from the application of the DC voltage by said voltage application circuit to the detection by said voltage detection circuit, and compares the charging time with a predetermined threshold time to determine if the occupant is seated on said seat or not.

2. The sitting detection system according to claim 1, wherein
said detection electrode is made of a conductive woven cloth, and
said conductive woven cloth is formed as a surface member of said seat, or is provided immediately under said surface member.

3. The sitting detection system according to claim 2, wherein
said conductive woven cloth is a woven cloth having conductive fibers woven therein at regular intervals.

4. The sitting detection system according to claim 1, wherein
said processing unit includes an oscillation circuit, and
said processing unit measures the charging time by counting the number of pulse signals of a fixed period which are generated by said oscillation circuit, during a period from the application of the DC voltage by said voltage application circuit to the detection by said voltage detection circuit.

5. The sitting detection system according to claim 1, wherein
said processing unit measures the charging time by applying the DC voltage in every predetermined period.

6. The sitting detection system according to claim 1, wherein
said processing unit measures the charging time in a state where the occupant is not seated in said seat, and sets the predetermined threshold time based on the measured charging time.

7. The sitting detection system according to claim 2, wherein
said processing unit includes an oscillation circuit, and
said processing unit measures the charging time by counting the number of pulse signals of a fixed period which are generated by said oscillation circuit, during a period from the application of the DC voltage by said voltage application circuit to the detection by said voltage detection circuit.

8. The sitting detection system according to claim 2, wherein
said processing unit measures the charging time by applying the DC voltage in every predetermined period.

9. The sitting detection system according to claim 2, wherein
said processing unit measures the charging time in a state where the occupant is not seated in said seat, and sets the predetermined threshold time based on the measured charging time.

10. The sitting detection system according to claim 3, wherein
said processing unit includes an oscillation circuit, and
said processing unit measures the charging time by counting the number of pulse signals of a fixed period which are generated by said oscillation circuit, during a period from the application of the DC voltage by said voltage application circuit to the detection by said voltage detection circuit.

11. The sitting detection system according to claim 7, wherein
said processing unit measures the charging time by applying the DC voltage in every predetermined period.

12. The sitting detection system according to claim 8, wherein
said processing unit measures the charging time in a state where the occupant is not seated in said seat, and sets the predetermined threshold time based on the measured charging time.

13. The sitting detection system according to claim 10, wherein
said processing unit measures the charging time by applying the DC voltage in every predetermined period.

14. The sitting detection system according to claim 11, wherein
said processing unit measures the charging time in a state where the occupant is not seated in said seat, and sets the predetermined threshold time based on the measured charging time.

15. The sitting detection system according to claim 13, wherein
said processing unit measures the charging time in a state where the occupant is not seated in said seat, and sets the predetermined threshold time based on the measured charging time.
